(19) United States
(12) Patent Application Publication
(10) Pub. No.: US 2026/0093969 A1
(43) Pub. Date: Apr. 2, 2026

(54) DIGITAL INJECTION-LOCKED OSCILLATOR

(71) Applicant: Commissariat à l'Energie Atomique et aux Energies Alternatives, PARIS (FR)

(72) Inventor: Franck BADETS, GRENOBLE (FR)

(21) Appl. No.: 19/341,044

(22) Filed: Sep. 26, 2025

(30) Foreign Application Priority Data
Oct. 1, 2024 (FR) 2410526

(51) Int. Cl. G06N 3/063; G06N 3/04; H03K 3/037

(52) U.S. Cl. CPC G06N 3/063; G06N 3/04; H03K 3/037

(57) ABSTRACT

The present description concerns a digital injection-locked oscillator (2). An adder (100) adds first and second digital words (OP2, OP1) and outputs a third result digital word (RES), the words being over N bits, with N an integer greater than 1. A register (102) updates the second word based on the third word (RES) at each period of a clock signal (clk). A first circuit (200) receives a reference signal (REF) at a natural frequency of an output bit (OUT), and a reference increment, inc_ref. The first circuit calculates a first value (valref) selectively equal to the reference increment inc_ref and to minus the reference increment inc_ref as a function at least of one state of the reference signal. The first circuit outputs the first word at least partly by adding the first value and a positive control number, P, the output bit being a bit of the second word.

### FIELD

The present disclosure generally concerns electronic circuits.

### BACKGROUND

More and more applications use neural computing.

Digital circuits based on Von-Neumman architectures implementing neural computing are known. However, the number of calculations per unit of time that these known circuits can implement is limited by memory access requirements, which are also power-consuming.

To overcome the limitations of these known digital circuits, known analog or mixed circuits implement neural computing in the time domain. Conversely to known analog circuits, which use the amplitude of an analog quantity (voltage or current) as an information vector, in the time domain the information vector is a temporal quantity (delay, frequency, phase, duty cycle). This allows a greater robustness to noise as compared with an analog or mixed circuit using an amplitude as information vector. Further, known analog or mixed circuits in the time domain can operate with lower power supply voltages than known analog or mixed circuits using an amplitude as information vector, which enables to decrease power consumption.

Several approaches are known to implement neuron circuits forming a neural network for the implementation of neural computing in the time domain.

A first approach is based on pulse density modulation. In this first approach, the information, for example, the result of the neural computing performed by a neuron, is encoded by a density of a pulse train, that is, by the number of pulses per unit of time in the pulse train. An example of such an approach is described in the article by A. Valentian et al, entitled “Fully Integrated Spiking Neural Network with Analog Neurons and RRAM Synapses” and presented in 2019 in IEEE International Electron Devices Meeting (IEDM), San Francisco. However, known analog neuron circuits based on pulse density modulation for time-domain computing are sensitive to PVT (Process, Voltage, Temperature) variations.

A second approach is based on pulse-width modulation (PWM). In this second approach, a data item is encoded by the width, or duration, of a pulse, which is used to control an integrator circuit accumulating a quantity encoding the weight associated with this data item.

Known analog neuron circuits based on pulse-width modulation for time-domain computing use a capacitive element to implement the accumulation function. The voltage across the capacitor is then converted into a pulse having a width proportional to the voltage of the capacitive element. An example of such an analog neuron circuit is, for example, described in the article by M. Yamaguchi, G. Iwamoto, Y. Nishimura, H. Tamukoh, and T. Morie, entitled “An Energy-Efficient Time-Domain Analog CMOS Binary Connect Neural Network Processor Based on a Pulse-Width Modulation Approach” and published in IEEE Access, vol. 9, pp. 2644-2654, 2021. These known analog neuron circuits are, however, limited to binarized neural network implementations, which limits the accuracy of calculations. In addition, the implementation of a neural network based on such analog neuron circuits is sensitive to PVT variations, which lead to mismatches between the neuron circuits.

Digital neuron circuits based on pulse-width modulation for time-domain computing are also known. Examples of such neuron circuits are, for example, described in the article by A. Sayal, S. S. T. Nibhanupudi, S. Fathima and J. P. Kulkarni, entitled “A 12.08-TOPS/W All-Digital Time-Domain CNN Engine Using Bi-Directional Memory Delay Lines for Energy Efficient Edge Computing” and published in IEEE Journal of Solid-State Circuits, vol. 55, no. 1, pp. 60-75, January 2020, and in the article by M. Mohey, M. Kosunen, J. Ryynanen and M. Andraud, entitled “Toward All-Digital Time-Domain Neural Network Accelerators for In-Sensor Processing Applications” and published in 2023 IEEE Nordic Circuits and Systems Conference (NorCAS), Aalborg, Denmark, 2023, pp. 1-6. A disadvantage of digital neuron circuits based on pulse-width modulation for time-domain computing is that, during the calculation of a weighted sum of input data where each input data item is multiplied by a weight which is associated thereto, the multiplications are implemented one after the other, which limits the computing speed. Further, these known digital neuron circuits are limited to binarized neural network implantations, which limits the accuracy of calculations.

A third approach is based on phases.

For example, known phase-based neuron circuits for time-domain computing use an oscillator having its oscillations activated or deactivated by a data input of a MAC (Multiply And Accumulate) operation, and having a frequency thus controlled by the weight applied to the data item. The oscillator output controls a counter which acts as a phase accumulator. However, in such examples of neuron circuits, in addition to the need for a digital-to-time converter to convert the input data item into an oscillation time of the oscillator, the weight-data pairs used for the calculation of the weighted sum of the input data are applied one after the other, which limits the computing speed. The article by Y. Toyama, K. Yoshioka, K. Ban, S. Maya, A. Sai and K. Onizuka, entitled “An 8 Bit 12.4 TOPS/W Phase-Domain MAC Circuit for Energy-Constrained Deep Learning Accelerators” and published in IEEE Journal of Solid-State Circuits, vol. 54, no. 10, pp. 2730-2742, October 2019, describes an example of such a neuron circuit.

As a further example, known phase-based neuron circuits for time-domain computing use an analog injection-locked oscillator (ILO) to implement a weighted sum of a plurality of phase shifts, as is, for example, the case in patent EP 4002698 A1. However, the analog implementation of these oscillators leads to mismatches during the implementation of a neural network. Further, these analog injection-locked oscillators are sensitive to the noise of active components, which limits the signal-to-noise ratio.

### SUMMARY

There exists a need to overcome all or part of the disadvantages of known neuron circuits for time-domain computing.

An embodiment overcomes all or part of the disadvantages of known neuron circuits for time-domain computing.

For example, an embodiment overcomes all or part of the disadvantages of known analog injection-locked oscillators by providing a digital injection-locked oscillator.

For example, an embodiment provides a phase shifter based on the provided digital injection-locked oscillator. Such a digital phase shifter may for example be used to convert a digital data item into a phase shift, for example at the input of a phase-based neural network.

For example, an embodiment provides a phase adder based on the provided digital injection-locked oscillator. Such a phase adder enables the implementation of a weighted sum of phases of input signals of the adder.

For example, an embodiment provides a neuron circuit based on the provided digital injection-locked oscillator. For example, in such a neuron circuit, the digital injection-locked oscillator enables the implementation of a weighted sum of phases of input signals of the neuron.

For example, an embodiment provides a neural network where the neuron circuits of the network are each based on the provided digital injection-locked oscillator.

An embodiment provides a digital injection-locked oscillator comprising:
an adder configured to add a first digital word over N bits with a second digital word over N bits and to output a result of the addition in the form of a third digital word over N bits, with N an integer greater than 1;
a register configured to update the second digital word based on the third digital word at each period of a clock signal;
a first circuit configured to:
   receive a reference signal at a reference frequency equal to a natural frequency of an output bit of the oscillator, and a reference increment, inc_ref,
   calculate a first value selectively equal to the reference increment inc_ref and to minus the reference increment inc_ref according to at least one binary state of the reference signal, and
   output the first digital word determined at least partly by adding the first value and a positive number, P, for controlling the oscillator, the output bit being a bit of the second word.

According to an embodiment, the output bit is the most significant bit of the second digital word.

According to an embodiment, the first circuit is configured to receive the output bit of the oscillator, and so that the first value is equal to the reference increment inc_ref if a result of an EXCLUSIVE OR between the output bit and the reference signal is in a first binary state and to minus increment inc_ref if the result of the EXCLUSIVE OR is in a second binary state.

An embodiment provides a digital phase shifter comprising the oscillator such as defined hereabove, in which number P belongs to a range of values centered on a number P0 and having a width equal to twice the absolute value of reference increment inc_ref, P0 being equal to 2^{L}.(Fref/Fclk), with L an index of the output bit in the second digital word, Fref the reference frequency, and Fclk the frequency of the clock signal, index L having a value in a range from 1 to N.

According to an embodiment, control number P determines a value of a phase shift of the output bit with respect to the reference signal.

According to an embodiment, the first digital word is equal to the sum of the first value and of the control number P of the oscillator.

According to an embodiment, the output bit is phase-shifted by p with respect to the reference signal, with:

$$φ = \frac{π}{2} + π \frac{P - {P}_{0}}{2 * inc\_ref} if {inc}_{ref} has a first polarity ,$$

$$and$$

$$φ = - \frac{π}{2} + π \frac{P - {P}_{0}}{2 * {inc}_{ref}} if {inc}_{ref} has a second polarity opposite to the first polarity$$

An embodiment provides a digital phase adder comprising:
the oscillator such as defined hereabove, in which:
the first circuit comprises K second circuits Lock_i, with i an integer index ranging from 1 to K and K an integer greater than or equal to 1, each second circuit Lock_i being configured to:
   receive the output bit, an increment inc_i, and an injection signal S_i at a frequency equal to the reference frequency with a phase shift ypi with respect to the reference signal, and
   output a second value out_i equal to increment inc_i if a result of an EXCLUSIVE OR between the output bit and the injection signal S_i is in a first binary state, and to minus increment inc_i otherwise; and
the first circuit is configured to deliver the first digital word equal to the sum of control number P, of the first value, and of the K second values val_i.

According to an embodiment, control number P is equal to 2^{L}.(Fref/Fclk), with L an index of the output bit in the second digital word, Fref the reference frequency, and Fclk the frequency of the clock signal, index L having a value in the range from 1 to N.

According to an embodiment, the output bit is phase-shifted by p with respect to the reference signal, with:

$$A = inc\_ref + {\sum }_{i = 1}^{i = K} inc\_i$$

$$φ = \frac{π}{2} + {\sum }_{i = 1}^{K} \frac{inc\_i \cdot D\_i}{A} if A has a first polarity ,$$

$$φ = - \frac{π}{2} + {\sum }_{i = 1}^{K} \frac{{inc}_{i} \cdot {D}_{i}}{A} if A has a second polarity opposite to the first polarity$$

An embodiment provides a neuron circuit comprising a first digital phase adder such as defined above, wherein K is equal to K1 in the first adder, the K1 phase shifts φ_i of the first adder correspond to K1 input values of the neuron circuit, K1 weights w_i of the neuron circuit determine the K1 increments inc_i of the first adder and the reference increment inc_ref of the first adder, and K1 is greater than or equal to 2.

According to an embodiment, the K1 increments inc_i of the first adder and the reference increment inc_ref of the first adder satisfy:

$$- inc\_i + {\sum }_{i = 1}^{i = K 1} w\_j \cdot inc\_i = - w\_j \cdot inc\_ref ,$$

with j an integer index ranging from 1 to K1, and

$$\vert inc\_ref \vert + {\sum }_{i = 1}^{i = K 1} \vert inc\_i \vert < P 1 , with \vert \vert$$

the absolute value operator, and P1 the value of the number P of the first adder.

According to an embodiment, the neuron circuit further comprises a second digital phase adder such as defined hereabove, wherein K is equal to K2 in the second adder and the output bit of the first adder corresponds to one of the K2 injection signals of the second adder.

According to an embodiment, the reference signal of the second adder has a same frequency as the reference signal of the first adder, and a phase shift between the reference signal of the first adder and the reference signal of the second adder is determined by a sign of the sum of the increments inc_i and inc_ref of the first adder, preferably so as to compensate for a phase shift introduced by the first adder.

An embodiment provides a neural network comprising M successive layers 600h of neurons, with M an integer greater than 1, and h an integer index ranging from 1 to M and increasing from inputs to outputs of the network, wherein:
each neuron is implemented by a neuron circuit such as defined hereabove, where the output bit of the first adder of the neuron circuit is the output bit of the neuron;
the neurons of the layers 600h of odd indices h all receive a same reference signal; and
each of the neurons of the layers 600h of even indices h receives a reference signal at a same frequency as the reference signal of the neurons of the layers 600h of odd index h, but with a phase shift between these two reference signals determined by a sign of the sum of the increments inc_i and inc_ref of each of the first adders of the neurons of the layers of odd index h.

An embodiment provides a neural network comprising a plurality of layers of neurons, wherein:
each neuron is implemented by a neuron circuit such as defined hereabove, the first adders of the neurons of the network all receive a same reference signal.

An embodiment provides a neural network comprising a plurality of neurons, each implemented by a neuron circuit such as defined hereabove. In each neuron circuit, each of the K1 injection signals of the first adder is an output bit of another neuron circuit in the network.

An embodiment provides a ring oscillator comprising Q digital oscillators, with Q an integer greater than 1, preferably than 2, wherein:
one of the Q digital oscillators is a digital injection-locked oscillator such as defined hereabove in which the first value is equal to the reference increment inc_ref of this digital injection-locked oscillator when the reference signal of this digital injection-locked oscillator is in a first binary state, and to minus the reference increment inc_ref otherwise;
each of the other Q-1 digital oscillators is:
   either a digital injection-locked oscillator such as defined hereabove, in which the first value is equal to the reference increment inc_ref of this digital injection-locked oscillator when the reference signal of this digital injection-locked oscillator is in a first binary state, and to minus the reference increment inc_ref otherwise,
   or a free-running digital oscillator comprising:
      an adder configured to add a first digital word over N bits to a second digital word over N bits and to output a result of the addition in the form of a third digital word over N bits;
      a register configured to update the second digital word based on the third digital word at each period of the clock signal, an output bit of said free-running oscillator being a bit of the third word and the first digital word being a word for controlling said free-running oscillator,
         wherein the Q digital oscillators are connected in a ring one after the other, the register of each digital oscillator being configured to be reset by a state of the output bit of the preceding digital oscillator in the ring.

### BRIEF DESCRIPTION OF THE DRAWINGS

The foregoing and other features and advantages will be discussed in detail in the following non-limiting description of specific embodiments in connection with the accompanying drawings, in which:

FIG. 1 shows an example of embodiment of a digital oscillator;

FIG. 2 shows an example of embodiment of a digital injection-locked oscillator, based on the digital oscillator of FIG. 1;

FIG. 3 shows an example of embodiment of a phase adder based on the oscillator of FIG. 2;

FIG. 4 shows an example of embodiment of a neuron circuit based on the phase adder of FIG. 3;

FIG. 5 shows an example of embodiment of a neural network;

FIG. 6 shows another example of embodiment of a neural network;

FIG. 7 shows another example of a neuron circuit; and

FIG. 8 shows a ring oscillator based on the oscillator of FIG. 2.

### DETAILED DESCRIPTION OF THE PRESENT EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, although the digital injection-locked oscillator provided in the present disclosure is adapted and advantageous for an implementation in a neuron circuit or in a phase-based neural network for time-domain computing, the provided digital injection-locked oscillator can be used in applications other than neural computing, and provide the same advantages, for example when it implements a phase adder or a phase shifter. As other examples of applications, the provided digital injection-locked oscillator can be used to implement a digital-to-time converter, a bandpass filter, or also a phase-to-digital converter.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, the term “coupled” is used to designate an electrical coupling between elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings. However, these terms do not presume the actual position and orientation of the device during its use.

Unless specified otherwise, the expressions “about”, “approximately”, “substantially”, and “in the order of” signify plus or minus 10% or 10°, preferably of plus or minus 5% or 5°.

In the present disclosure, unless otherwise indicated, the expression “ranging from a first value to a second value” means ranging from the first value included to the second value included.

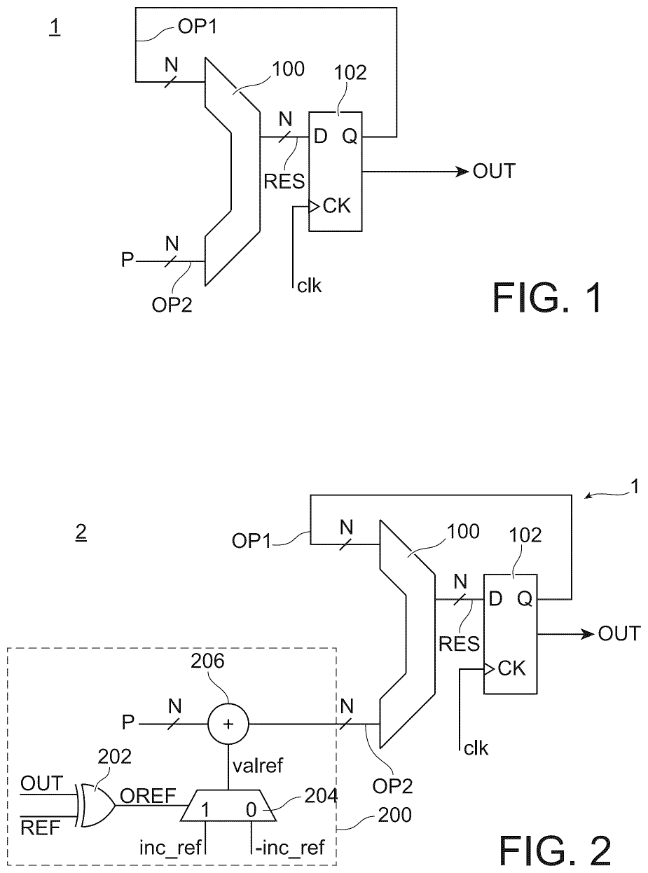

FIG. 1 shows an example of embodiment of a digital oscillator 1. As will be discussed in more detail in relation with FIG. 2, this oscillator 1 enables the implementation of a digital injection-locked oscillator.

Digital oscillator 1 comprises a digital circuit 100 configured to calculate a sum of a digital signal OP1 over N bits and of a digital signal OP2 over N bits, and to output a digital signal RES over N bits corresponding to the result of this sum. Signals OP1, OP2, and RES are thus N-bit digital words, each encoding a value. N is an integer greater than 1, for example greater than 10. Circuit 100 is, for example, called an N-bit adder.

Oscillator 1 also comprises a register 102 over N bits. Register 102 is controlled by a clock signal clk at a frequency Fclk. Register 102 is configured to update signal OP1 based on signal RES at each period of signal clk, for example at the beginning of each period of signal clk corresponding, for example, to a rising edge of signal clk. Between two successive updates, register 102 stores signal OP1, or, in other words, holds signal OP1 at its current value.

For example, register 102 comprises a data input D configured to receive the output word RES of adder 100, a synchronization input CK configured to receive signal clk, and an output Q configured to deliver signal OP1. As an example, register 102 comprises N D-type flip-flops, each flip-flop receiving a bit of signal RES and delivering a corresponding bit of signal OP1.

The assembly of adder 100 and of register 102 forms a phase accumulator.

Oscillator 1 delivers an output bit OUT. This bit OUT corresponds to a bit of signal OP1. For example, calling OP1n the bits of signal OP1, with n an integer index ranging from 1 to N and increasing towards the most significant bits of signal OP1, signal OUT is the bit OP1n of index n equal to L, with L an integer belonging to the range from 1 to N. Thus, in FIG. 1, as an illustration, the bit OUT of signal OP1 is shown as delivered by register 102.

Preferably, L is equal to N, or, in other words, bit OUT corresponds to the most significant bit of word OP1.

Oscillator 1 further receives a control number P. Number P is preferably positive, so that number P is added, by adder 100, to number OP1. As another example, number P is negative and adder 100 implements a subtraction of number P from number OP1, or, in other words, number P is positive and the operation implemented by adder 100 is a subtraction. In the present description, there is called adder a circuit configured to add or subtract two operands that it receives. Number P is supplied to oscillator 1 in the form of a digital signal, or digital word, over N bits. Word OP2 is determined at least partly by number P. More particularly, in the example of FIG. 1, word OP2 is equal to number P. For example, in FIG. 1, word OP2 encodes number P.

It can be shown that the frequency F0 of bit OUT is defined by the following equation:

$$F 0 = \frac{P}{{2}^{L}} \cdot Fclk \qquad [ Math 1 ]$$

Preferably, P and L are selected so that F0 is smaller than Fclk/2, whereby, preferably, P is selected to be smaller than 2^{L-1}.

When the index L of the bit OUT in word OP1 is equal to N, that is, when bit OUT is the most significant bit in word OP1, the frequency F0 of bit OUT is defined by the following equation:

$$F 0 = \frac{P}{{2}^{N}} \cdot Fclk \qquad [ Math 2 ]$$

Thus, the selection of value P enable to modify the value of the frequency F0 of bit OUT. Frequency F0 is, for example, called the natural frequency of oscillator 1.

As oscillator 1 is not, in FIG. 1, injection-locked, this oscillator is for example called free-running digital oscillator.

FIG. 2 shows an example of embodiment of a digital injection-locked oscillator 2, based on the digital oscillator 1 of FIG. 1.

Oscillator 2 comprises oscillator 1. However, as compared with the example of FIG. 1, where word OP2 receives number P, that is, the N-bit digital word encoding number P, in injection-locked oscillator 2, word OP2 is delivered by a circuit 200, based on number P. In FIG. 2, circuit 200 is delimited by dotted lines.

Circuit 200 enables oscillator 2 to be injection-locked.

Circuit 200 enables injection locking by delivering signal OP2 so that it corresponds to the number P to which is selectively added or subtracted a reference increment inc_ref based on at least the binary state of a reference signal REF at a reference frequency Fref.

In the circuit 200 of the example of FIG. 2, reference increment inc_ref is selectively added or subtracted at the rate of a reference frequency Fref of a reference signal REF and according to the binary state of bit OUT. In other words, in the circuit 200 of the example of FIG. 2, to obtain word OP2, reference increment inc_ref is selectively added to or subtracted from number P based on the binary state of a signal determined by reference signal REF and bit OUT. Thus, in the example of FIG. 2, word OP2 is determined by control number P, reference frequency Fref, reference increment inc_ref, and the output bit OUT of oscillator 2.

For example, the circuit 200 of FIG. 2 is configured to receive bit OUT, signal REF at frequency Fref, and reference increment inc_ref. Circuit 200 then calculates, or determines, a value valref. Value valref is equal to increment inc_ref if the result OREF of a Boolean XOR operation between signal REF and bit OUT is in a first binary state, and value valref is equal to minus increment inc_ref (−inc_ref in FIG. 2) otherwise, that is, when the result OREF of this XOR operation is in a second binary state. Circuit 200 then delivers signal OP2 at least partly determined by a sum between number P and value valref. In the example of FIG. 2, word OP2 is equal to the sum of number P and of value valref. Preferably, increment inc_ref and value valref are digital signals over a plurality of bits, for example over N bits, that is, digital words encoding the value of increment inc_ref and value valref. As an example, reference increment valref is positive, although, in other examples, increment valref may be negative.

As an example, in the circuit 200 of FIG. 2, to generate value valref, circuit 200 comprises a logic gate 202 implementing an EXCLUSIVE OR operation, a selection circuit 204, and a digital adder 206.

Gate 202 receives signal REF and bit OUT, and delivers the binary signal OREF resulting from the exclusive OR between signals REF and OUT.

Selection circuit 204 delivers value valref equal to increment inc_ref when signal OREF is in a first binary state, for example a first binary state corresponding to the logic ‘1’, and equal to minus increment inc_ref when signal OREF is in a second binary state, for example a second binary state corresponding to the logic ‘0’. As an example, circuit 204 is a multiplexer receiving increment inc_ref and minus increment inc_ref (“−inc_ref” in FIG. 2), and delivering value valref, multiplexer 204 being controlled by signal OREF.

Adder 206 is configured to receive value valref, to add it to number P, and to output the signal OP2 resulting from this addition.

In oscillator 2, after several periods of signal REF, oscillator 2 locks. The frequency of bit OUT becomes equal to reference frequency Fref, but signal OUT is phase-shifted with respect to signal REF. The value of this phase shift depends on the value of reference increment inc_ref, and on the difference between frequency Fref and the natural frequency F0 of oscillator 2.

This locking behavior is observed when frequency Fref has a value belonging to a locking range of oscillator 2. This locking range has a width (or range) ΔF defined by the following equation:

$$Δ F = \frac{inc\_ref}{{2}^{L - 1}} \cdot Fclk \qquad [ Math 3 ]$$

In the above equation [Math. 3], L is equal to N when bit OUT corresponds to the most significant bit of word OP1.

The locking range is centered on the natural frequency F0 of the oscillator.

In the specific case where number P is equal to a value P0 such that the natural frequency F0 of oscillator 2 is equal to injection frequency Fref, once oscillator 2 is locked, the phase shift between signal OUT and signal REF has an absolute value equal to Π/2 and a sign which depends on the sign of reference increment inc_ref. For example, taking the example of FIG. 2 where value valref is equal to reference increment inc_ref if bit OREF is set to ‘1’, this phase shift is equal to Π/2 when increment inc_ref is positive, and to −Π/2 when increment inc_ref is negative. For the natural frequency F0 and the reference frequency Fref to be equal, number P is equal to value P0 defined by the following equation:

$$P 0 = \frac{Fref}{Fclk} \cdot {2}^{L} \qquad [ Math 4 ]$$

When the index L of bit OUT in word OP1 is equal to N, that is, when bit OUT is the most significant bit of signal OP1, value P0 is defined by the following equation:

$$P 0 = \frac{Fref}{Fclk} \cdot {2}^{N} \qquad [ Math 5 ]$$

Once oscillator 2 is locked to frequency Fref, the phase shift between bit OUT and signal REF can be modified by changing the natural frequency F0 of oscillator 2, that is, by changing the value of number P with respect to the value P0 for which the natural frequency F0 of oscillator 2 is equal to reference frequency Fref.

Thus, oscillator 2 can be used as a digital phase shifter controlled by digital word P. In other words, oscillator 2 can be used as a digital-to-phase shift converter configured to convert digital word P into a corresponding phase shift between signal OUT and reference signal REF.

As an example, such a digital-to-phase shift converter can be used as the input to a phase-based neural network to implement neural computing, so as to convert a digital input data item of the network into a corresponding phase shift. The data item to be converted determines control word P and is converted into a corresponding phase shift of signal OUT with respect to signal Fref.

For example, the phase shift φ of signal OUT with respect to signal REF is defined by the following relations:

$$φ = \frac{π}{2} + π \frac{P - {P}_{0}}{2 * inc\_ref} si inc\_ref > 0 \qquad [ Math 6 ]$$

$$φ = - \frac{π}{2} + π \frac{P - {P}_{0}}{2 * inc\_ref} si inc\_ref < 0 \qquad [ Math 7 ]$$

The equations [Math. 6] and [Math. 7] given hereabove apply to the example of FIG. 2 where gate 202 is an exclusive OR gate, valref receives inc_ref when the output of gate 202 is active (at ‘1’), and valref receives −inc_ref when the output of gate 202 is inactive (at ‘0’). However, those skilled in the art are capable of generalizing the above equations [Math. 6] and [Math. 7] to other examples. For example, in the case where gate 202 is an exclusive OR gate, valref receives −inc_ref when the output of gate 202 is active (at ‘1’), and valref receives inc_ref when the output of gate 202 is inactive (at ‘0’), for example because an inverter is arranged between the output of gate 202 and the control input of circuit 204, then the sign of the fixed phase shift of value Π/2 is positive when inc_ref is negative, and negative when inc_ref is positive. Thus, more generally, the equation [Math. 6] is valid when inc_ref is of a first polarity, and the equation [Math. 7] is valid when inc_ref is of a second polarity opposite to the first one, this validity further depending on the way in which circuit 204 is controlled by the output of gate 202.

For example, there results from the above two relations that the range of variation of the value of number P which enables to obtain range of variation of the phase shift φ of width Π is centered on P0 and has an extension ΔP defined by the following relation:

$$Δ P = 2 \cdot \vert inc\_ref \vert , with \vert \vert the absolute value function \qquad [ Math . 8 ]$$

For example, to obtain a phase shift φ having a value in a range from 0 to Π when increment inc_ref is positive and a value in a range from −Π to 0 when increment inc_ref is negative, number P has a value in a range from a value Pmin to a value Pmax defined by the following relations:

$$P min = P 0 - \vert inc\_ref \vert \qquad [ Math 9 ]$$

$$P max = P 0 + \vert inc\_ref \vert \qquad [ Math 10 ]$$

The gain G of phase shifter 2, which corresponds to the slope of variation of phase shift φ as a function of number P, is defined by the following relation:

$$G = \frac{π}{2 \cdot inc\_ref} \qquad [ Math 11 ]$$

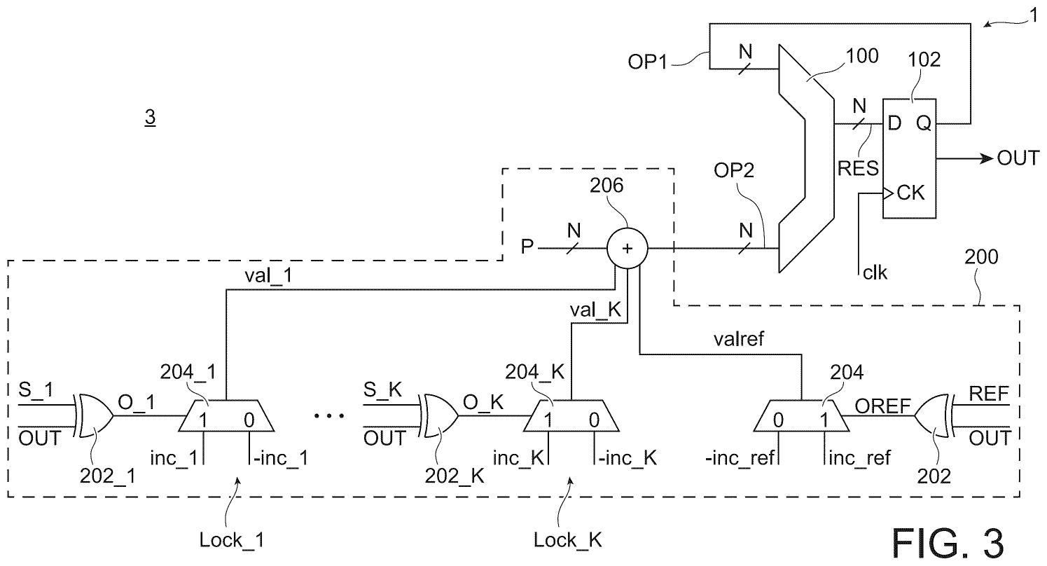

FIG. 3 shows an example of embodiment of a phase adder 3.

Phase adder 3 has many elements in common with injection-locked oscillator 2, and only the differences between these two devices 2 and 3 are here highlighted.

Phase adder 3 comprises oscillator 1 and a circuit 200 delivering digital word OP2 at least partly based on the sum of value valref and of number P, value valref being selectively equal to increment inc_ref and to minus increment inc_ref according at least to reference signal REF.

In FIG. 3, as in FIG. 2, value valref is equal to increment inc_ref if the result OREF of an exclusive OR between bit OUT and signal REF is in a first binary state, and to minus increment inc_ref otherwise.

In FIG. 2, circuit 200 is configured so that word OP2 is the result of the sum of value valref and of number P, and signal OP2 is then determined by the sum of value valref and of number P. Conversely, in the circuit 200 of phase adder 3, signal OP2 is not only determined by the sum of value valref and of number P.

Indeed, in adder 3, not only is circuit 200 configured, as in oscillator 2, to calculate value valref and add it to number P, but, further, for an integer index i ranging from 1 to K, with K an integer greater than or equal to 1, to:
receive K injection signals S_i (S_1 and S_K in FIG. 3), each signal S_i being at reference frequency Fref and exhibiting a phase shift φ_i with respect to signal REF. Preferably, each phase shift φ_i belongs to the value range from −Π to Π;
receive K increments inc_i (inc_1 and inc_K in FIG. 3), each increment inc_i being preferably received in the form of a digital word, for example over N bits;
output K val_i values (val_1 and val_K in FIG. 3), each val_i value being, in the example of FIG. 3, equal to increment inc_i if the result O_i (O_1 and O_K in FIG. 3) of a Boolean XOR operation between signal S_i and bit OUT is in a first binary state and to minus increment inc_i, that is, −inc_i (−inc_1 and −inc_K in FIG. 3), if the result of the Boolean EXCLUSIVE OR operation between signal S_i and bit OUT is in a second binary state. Preferably, each value val_i is provided in the form of a digital word, for example over N bits;
add values val_i to number P to obtain word OP2.

Thus, the circuit 200 of phase adder 3 is configured to deliver word OP2 equal to the sum of number P, of value valref, and of the K values val_i.

When the reference frequency F0 of oscillator 1 is equal to frequency Fref, that is, when P is equal to value P0, it can be shown that the phase shift φ between bit OUT and signal REF is defined by the following relations in the example of FIG. 3:

$$A = inc\_ref + {\sum }_{i = 1}^{i = K} inc\_i \qquad [ Math 12 ]$$

$$φ = \frac{π}{2} + {\sum }_{i = 1}^{K} \frac{inc\_i \cdot φ\_i}{A} si A > 0 \qquad [ Math 13 ]$$

$$φ = - \frac{π}{2} + {\sum }_{i = 1}^{K} \frac{inc\_i \cdot φ\_i}{A} si A < 0 \qquad [ Math 14 ]$$

Thus, adder 3 delivers bit OUT with a phase shift φ relative to reference signal REF which is determined by the weighted sum of phase shifts φ_i, each phase shift φ_i being weighted by the value of the corresponding increment inc_i divided by number (or sum) A. For example, the phase shift φ of bit OUT with respect to reference signal REF is equal to this weighted sum plus a phase offset having, for example, a fixed absolute value equal to Π/2 and a sign determined by the sign of number A.

However, in the same way as this has been described for formulas [Math. 6] and [Math. 7], the use of formula [Math. 13] and [Math. 14] more generally depends on the polarity of A. Indeed, formula [Math. 13] is valid for a first polarity of A and formula [Math. 14] is valid for a second polarity of A. The fact for the first polarity to be the positive or negative polarity depends in particular on the polarity of each of increments inc_ref and inc_i and/or on the way in which circuits 204 and 204_i are controlled by the respective gates 204 and 204_i.

It should be noted that, in the above description, phase shift Y corresponds to the phase shift of bit OUT with respect to signal REF. However, those skilled in the art will be capable, knowing the value of the phase shift φref of signal REF with respect to another reference signal which is not used as an injection signal in circuit 200 but which is at frequency Fref, to determine, from the above relations, the phase shift of signal OUT with respect to this other reference signal.

Further, although this is not detailed herein, in the same way as in the circuit 2 of FIG. 2, in the circuit 3 of FIG. 3, it is possible to vary the value of phase shift φ by modifying the value of number P with respect to value P0.

For example, in FIG. 3, circuit 200 comprises K circuits Lock_i (Lock_1 and Lock_K in FIG. 3). Each circuit Lock_i is configured to receive bit OUT, signal S_i at frequency Fref, and increment inc_i. Each circuit Lock_i then calculates, or determines, a value val_i equal to increment inc_i if the result O_i of an EXCLUSIVE OR Boolean operation between signal S_i and bit OUT is in the first binary state, and minus increment inc_i (−inc_1 and −inc_K in FIG. 3) otherwise, that is, when the result O_i of this operation is in the second binary state. Circuit 200 then delivers signal OP2 equal, in the example of FIG. 3, to the sum of number P, of value valref, and of the K values val_i. Preferably, each increment inc_i is a digital signal over a plurality of bits, for example N bits, that is, a digital word encoding the value of increment inc_i. Each increment inc_i may be positive or negative. Preferably, each value val_i is a digital signal over a plurality of bits, for example over N bits, that is, a digital word encoding value val_i.

As an example, to generate value val_i, each circuit Lock_i comprises a logic gate 202_i (202_1 and 202_K in FIG. 3) implementing the EXCLUSIVE OR operation and a selection circuit 204_i (204_1 and 204_K in FIG. 3).

Each gate 202_i receives signal S_i and bit OUT, and outputs the binary signal O_i resulting from the EXCLUSIVE OR between signals S_i and OUT.

Each selection circuit 204_i is configured to deliver value val_i equal to increment inc_i when signal O_i is in the first binary state, corresponding to the logic ‘1’, and to deliver value val_i equal to minus increment inc_i when signal O_i is in the second binary state, corresponding to the logic ‘0’. As an example, each circuit 204_i is a multiplexer receiving increment inc_i and minus increment inc_i, and delivering value val_i, multiplexer 204_i being controlled by signal O_i.

Adder 206 is configured to receive value valref and values val_i, to add these values val_i and valref to number P, and to deliver signal OP2 as the result of this addition.

An advantage of phase adder 3 is that it can be used as a basis for implementing a neuron circuit enabling phase-based time-domain computing.

Indeed, each phase shift φ_i can then correspond to an input data item of the neuron, and each of increments inc_i and inc_ref can be determined by the weights w_i applied to these input data. For example, each of increments inc_i and inc_ref can be determined so that the phase shift φ between bit OUT and signal REF is equal to the sum of products φ_i.w_i and of a phase shift having an absolute value Π/2 and a sign determined by the sign of sum A. For example, the sign of the phase shift is the sign+(positive phase shift) when number A is positive, and is the sign−(negative phase shift) when number A is negative.

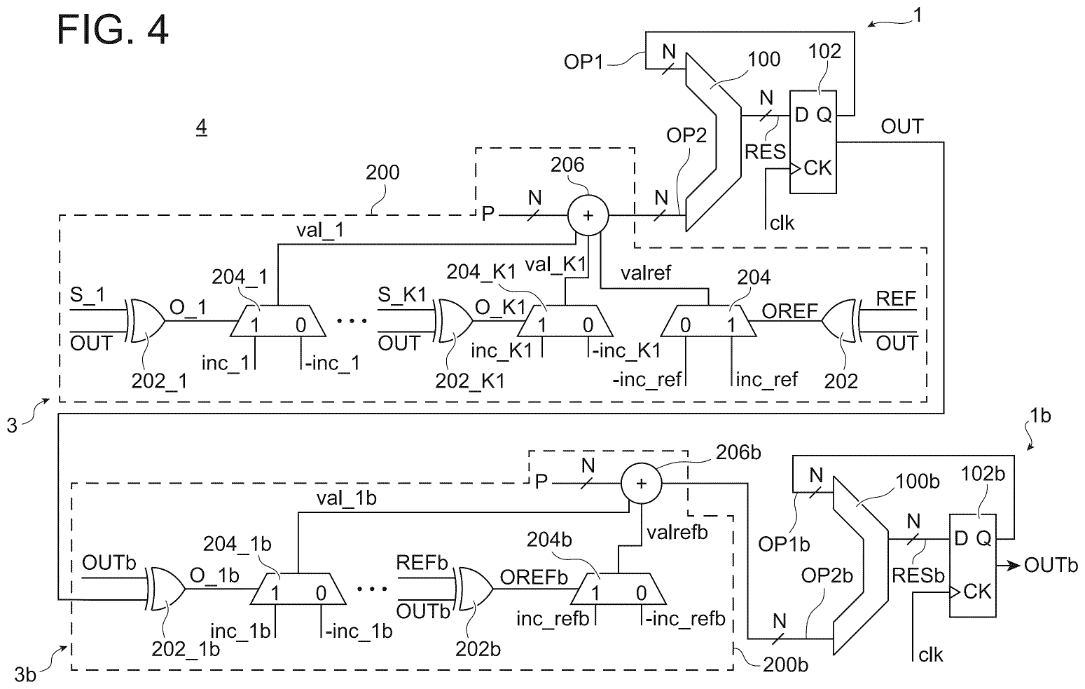

FIG. 4 shows an example of a neuron circuit 4 based on the phase adder 3 of FIG. 3.

In FIG. 4, neuron circuit 4 comprises adder 3, where K=K1, with K1 an integer greater than or equal to 2.

In this case, the values of the K1 increments inc_i and of reference increment inc_ref can be determined by solving a system of K1+1 equations with K1+1 unknowns, namely the values of the K1 increments inc_i and the value of increment inc_ref. This system is defined by the following K1+1 equations:

$$- inc\_j + {\sum }_{i = 1}^{i = K 1} w\_j \cdot inc\_i = - w\_j \cdot inc\_ref , \qquad [ Math 15 ]$$

$$pour j un indice entier allant de 1 à K 1$$

$$\vert inc\_ref \vert + {\sum }_{i = 1}^{i = K 1} \vert inc\_i \vert < P 1 \qquad [ Math 16 ]$$

The value of inc_ref is selected so that equation [Math 16] is verified, the number P1 of equation [Math 16] being equal to the control number P of adder 3 in FIG. 4, so that Fref is equal to the natural frequency of the oscillator 1 of adder 3, that is, (Fref/Fclk).2^{L}.

As an explanation, the above equation [Math 15] corresponds to the following equation system:

$$[ Math 17 ]$$

$$\{ \begin{matrix}( w\_ 1 - 1 ) \cdot inc\_ 1 + w\_ 1 \cdot inc\_ 2 + … + w\_ 1 \cdot inc\_K1 = - w\_ 1 \cdot inc\_ref \\ w\_ 2 \cdot inc\_ 1 + ( w\_ 2 - 1 ) \cdot inc\_ 2 + … + w\_ 2 \cdot inc\_K1 = - w\_ 2 \cdot inc\_ref \\ … \\ \begin{matrix}w\_K1 \cdot inc\_ 1 + w\_K1 \cdot inc\_ 2 + … + ( w\_K 1 - 1 ) \cdot inc\_K1 = \\ - w\_K1 \cdot inc\_ref\end{matrix}\end{matrix}$$

In FIG. 4, the adder 3 of neuron circuit 4 is configured to implement the calculation of the weighted sum of phase shifts φ_i where each phase shift is weighted by a corresponding weight w_i, and to output signal OUT, which has a phase shift φ with respect to signal REF representative of the result of this weighted sum.

It may be desirable, in a neuron circuit, also called neuron, for an activation function to be applied to the result of the weighted sum operation.

Thus, according to an embodiment, neuron circuit 4 further comprises an additional adder 3, designated with reference 3b in FIG. 4. Adder 3b is used to implement a function of activation of neuron circuit 4. In alternative embodiments, this adder 3b is omitted, and the output bit OUT of phase adder 3 is the output bit of neuron 4.

Additional adder 3b is identical to the adder 3 of FIG. 3, with the difference that the elements 100, 102, 200, OUT, OP1, OP2, and RES of adder 3b are designated with the respective references 100b, 102b, 200b, OUTb, OP1b, OP2b, and RESb. Further, in adder 3b, number K is equal to K2, with K2 equal to 1 in the example of FIG. 4.

The output signal OUT of adder 3 is an input injection signal for adder 3b. In other words, the signal OUT of adder 3 corresponds to one of the K2 signals S_i of adder 3b, and, more specifically, to the signal S_1 of adder 3b in the example of FIG. 4.

In the circuit 200b of adder 3b, a “b” is placed at the end of references REF, S_i, 202, 202_i, 204, 204_i, 206, O_i, val_i, inc_i, −inc_i OREF, valref, inc_ref, and −inc_ref.

The reference signal REFb of adder 3b has the same frequency as the signal REF of adder 3, but is preferably phase-shifted with respect to signal REF.

As an example, the value of the phase shift between signal REF and signal REFb is determined so as to compensate for the phase shift Π/2 or −Π/2 introduced by phase adder 3 between signal OUT and signal REF. As an example, the phase shift between signals REF and REFb is then determined by the sign of the sum of increments inc_i.

As an example, the phase shift between signal REFb and signal REF is selected to be equal to the phase shift Π/2 or −Π/2 between bit OUT and signal REF, and, further, the increments inc_ib are determined so that the sign of the sum of increments inc_i and inc_ref is opposite to the sign of the sum of increments inc_ib and inc_refb so that the fixed phase shift introduced by adder 3b compensates for that of adder 3. Since the sign of the phase shift of absolute value equal to Π/2 introduced by adder 3 between bit OUT and signal REF is determined by the sign of the sum of increments inc_ref and inc_i, the phase shift between signals REF and REFb is determined by the sign of the sum of increments inc_ref and inc_i.

As an example, it is possible to invert the polarity of signal REFb with respect to that of signal REF, or, in other words, to apply a Π phase shift to the phase shift of signal REFb with respect to signal REF, which amounts to inverting the sign of the increment inf_refb associated with signal REFb.

More generally, it is possible, in a given phase adder, for example phase adder 3 or 3b, to select the fixed phase shift between the reference frequency signal Fref supplied to the adder, for example, the respective signal REF or REFb, and a general reference frequency signal Fref, as well as the sign of the sum of the increments of the adder, for example respectively the sum of increments inc_i and inc_ref or the sum of increments inc_ib and inc_refb, so as to compensate for a fixed phase shift introduced by the adder between its output bit and the general reference signal.

Further, it can be understood from the above examples that it is possible to obtain, by selecting the values of the increments in adder 3b, all possible combinations of gain values in adder 3b between the input phase of adder 3b, that is, the phase shift of signal OUT with respect to signal REFb, and the output phase of adder 3b, that is, the phase shift of signal OUTb with respect to signal REFb, and that this gain has a value which depends on the input phase of adder 3b. For example, it is possible to implement, in adder 3b, a gain following a sigmoid-type function.

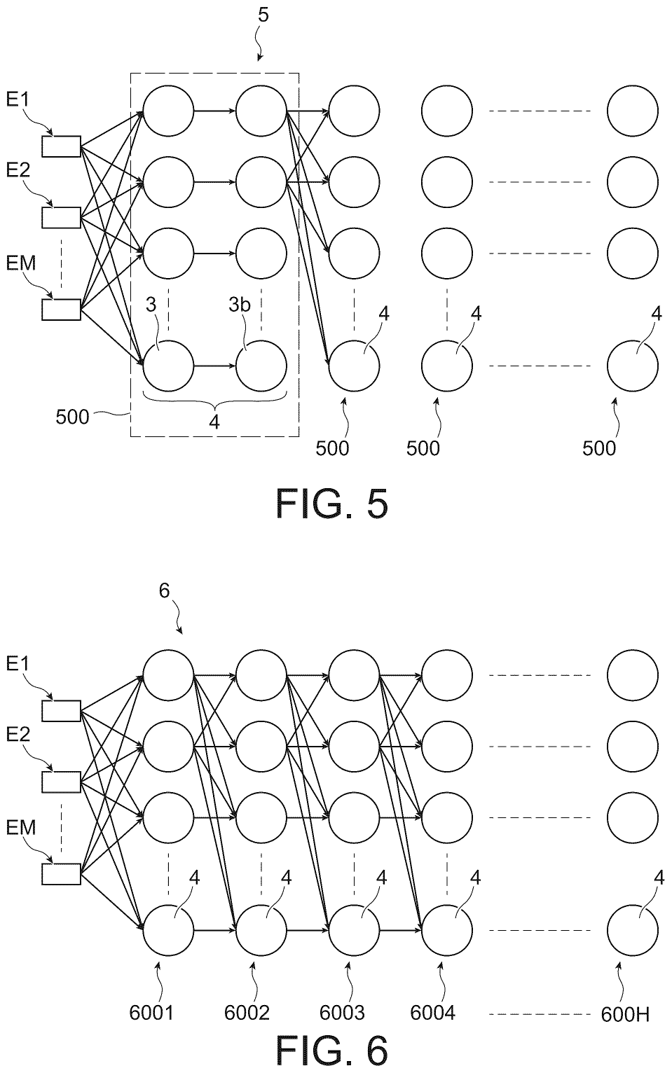

FIG. 5 shows an example of embodiment of a network 5 of neurons 4.

In the example of FIG. 5, network 5 receives M input signals Em (E1, E2, and EM in FIG. 5), with M an integer greater than 1, and m an integer index ranging from 1 to M. As an example, each signal Em is a signal at the reference frequency Fref, but with a phase shift φm relative to a reference signal of the network 5 which is determined by an input value of network 5. As an example, each signal Em is supplied by a digital-to-phase converter, for example by a phase shifter 2.

Network 5 comprises a plurality of layers 500 of neurons, that is, a plurality of layers 500 of neuron circuits 4.

In the example of FIG. 5, each neuron 4 comprises a phase adder 3 implementing the weighted sum of its inputs by the associated weights, followed by a phase adder 3b implementing an activation function.

As an example, in FIG. 5 where each neuron 4 comprises two phase adders 3 and 3b, although this is not detailed in the drawing, all the neurons 4 of network 5 receive the same reference signal REF, which is the reference signal of the adders 3 of neurons 4. In this case, in each neuron 4, the reference signal REFb of adder 3b is at the same frequency as signal REF, but preferably with a phase shift relative to signal REF which is determined by the sign of the sum of the increments in each of adders 3, so as to compensate, in each neuron 4, for the phase shift of absolute value Π/2 introduced by adder 3 with respect to the reference signal REF of neuron 4. Thereby, in the entire network 5, the phase shifts are all determined (or referenced) with respect to a single reference signal REF of neurons 4. This reference signal REF is, for example, the reference signal of the phase shifts in network 5. For example, in each neuron 4, the adder 3b of neuron 4 receives a reference signal REFb which is in positive or negative quadrature with respect to the signal REF of neuron 4. For example, the polarity of the quadrature of signal REFb with respect to signal REF is determined by the sign of the sum of the increments inc_ref and inc_i of the adder 3 of neuron 4.

As another example, the phase shift of signal REFb with respect to signal REF in a given neuron 4 may be different from the phase shift of signal REFb with respect to signal REF in another neuron 4, for example another neuron 4 of the same layer 500.

As still another example, a signal at frequency Fref is used as a general reference signal of network 5, and, in each neuron 4, the phase shift of signal REF with respect to this general reference signal and the phase shift of signal REFb with respect to this general reference signal are determined so as to compensate for the fixed phase shift of the output bit of neuron 4 with respect to the general reference signal of the network. In other words, in each neuron 4, the phase shifts of the signals REF and REFb of neuron 4 with respect to the general reference signal are determined to cancel the fixed phase shift introduced by the adder 3 of neuron 4 between the signal REF and the output bit OUT of this adder 3 and the fixed phase shift introduced by the adder 3b of neuron 4 between the signal REFb and the output bit OUTb of this adder 3b.

There has been described in relation with FIG. 5 the case of a network 5 of neurons 4 in which each neuron 4 comprises an adder 3 followed by an adder 3b implementing an activation function.

As a variant, the activation function can be implemented in a neuron 4, with no phase adder 3b.

For example, taking the example of neuron 4 of FIG. 4, the activation function can be implemented in neuron 4 without adder 3b, which is then omitted, the bit OUT of adder 3 then being the output signal (or bit) of neuron 4. For this purpose, the weights w_i applied to the inputs S_i of neuron 4, via increments inc_i, are each the result of a multiplication between the gain of the activation function to be applied and a weight w′_i to be applied to the input data item encoded by the phase shift of signal S_i. Increments inc_i and inc_ref are calculated from the weights w_i already comprising the gain of the activation function, whereby the activation function has already been applied in the phase shift of the output bit OUT of adder 3 with respect to the signal REF of adder 3.

FIG. 6 shows another example of embodiment of a network 6 of neurons 4.

In the example of FIG. 6, network 6 receives M input signals Em (E1, E2, and EM in FIG. 6), with M an integer greater than 1, and m an integer index ranging from 1 to M. As an example, each signal Em is a signal at reference frequency Fref, but with a phase shift φm with respect to a reference signal of network 6 which is determined by an input value of network 6.

The network comprises H successive layers 600h of neurons, with H an integer greater than 2, and h an index ranging from 1 to H. The index h of the successive layers 600h increases from inputs to outputs of network 6. In the example of FIG. 6, H is greater than 4, and only the layers 6001, 6002, 6003, 6004, and 600H of the network are shown.

In the example of FIG. 6, the output bit OUT of the adder 3 of the neuron is the output bit of the neuron. In other words, in the example of FIG. 6, each neuron lacks the adder 3b implementing an activation function.

In the example of FIG. 6, each neuron 4 comprises a phase adder 3 implementing the weighted sum of these inputs by the associated weights. Each neuron 4 may further implement an activation function, with no additional phase adder 3b, by multiplying the weights by the gain of the activation function as previously indicated.

As an example, although this has not been detailed in FIG. 6, the neurons 4 of the layers 600h of odd indices all receive the same reference signal REF. On the other hand, the reference signals supplied to the neurons 4 of the layers 600h of even indices h are at the same frequency as the signal REF of the layers 600h of even index h, but have different phase shifts with respect to the signal REF of the layers 600h of odd indices h. More specifically, each neuron 4 of each layer 600h of even index h receives a signal REF having a phase shift relative to the signal REF of the preceding layer 600h of odd index h is determined by the sign of the sum of increments inc_i and inc_ref in each of the adders 3 of the neurons 4 of this preceding layer. This phase shift is, for example, determined so as to compensate for the phase shift of absolute value Π/2 introduced by the adders 3 of the neurons 4 of the previous layer 600h. This phase shift is, for example, a phase shift of absolute value equal to Π/2 and having a sign (or polarity) determined by the sign (or polarity) of the sum of the increments inc_i and inc_ref of the neuron 4 of the preceding layer 600h. Thereby, throughout the entire network 6, the phase shifts of the output bits of neurons 4 are all determined (or referenced) with respect to a single reference signal, for example the signal REF of the layers 600h of odd h indices. This reference signal REF is, for example, the reference signal of phase shifts in network 6.

As another example, in each neuron 4, the phase shift of the signal REF received by this neuron 4 with respect to a general reference signal of network 6 at frequency Fref and/or the sign of the sum of the increments of the adder of neuron 4 are determined to compensate for the fixed phase shift Π/2 or −Π/2 introduced by this neuron between its output bit and its reference signal REF. Thereby, all throughout network 6, the phase shifts of the output bits of neurons 4 are all determined (or referenced) with respect to a single reference signal, that is, the general reference signal of network 6.

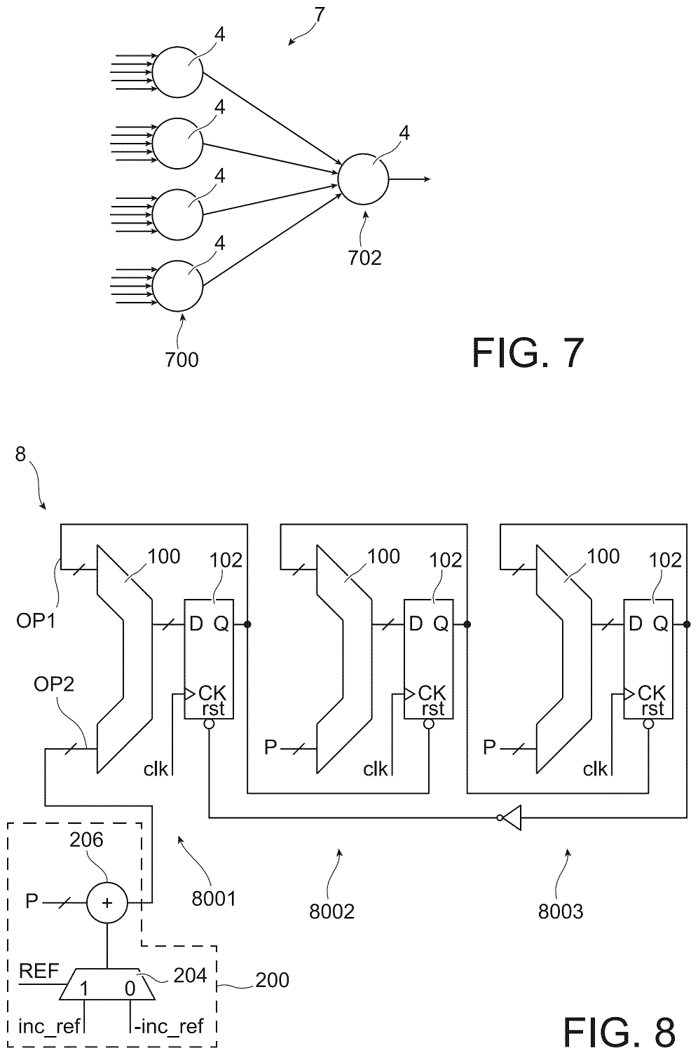

FIG. 7 shows another example of a neuron circuit 7.

In FIG. 7, as compared with the previously-described neurons 4, neuron 7 comprises a first layer or stage 700 of a plurality of neurons 4, followed by a second layer 702 or stage with one neuron 4. The input signals of neuron 7 are distributed between the neurons 4 of layer 700, and the neuron 4 of layer 702 is configured to deliver an output signal of neuron 7 based on the output signals of the neurons 4 of layer 700.

In other words, the neuron 7 of FIG. 7 corresponds to a network of neurons 4 with only two layers 700 and 702 of neurons 4, in which the inputs of neuron 7 are distributed over the neurons 4 of layer 700, and the single neuron 4 of layer 702 is configured to deliver the output signal of neuron 7 based on the output signals of the neurons 4 of layer 700.

For example, the output signal of neuron 7 has a phase shift with respect to a reference signal REF supplied to the neurons 4 of layer 700 which is equal to the sum of the phase shifts of the output signals of the neurons 4 of layer 700, or, in other words, the weights implemented by the neuron 4 of layer 702 are unit weights.

Based on the description made hereabove in relation with FIGS. 5 and 6 of neural networks 4, those skilled in the art will be capable of determining the phase shift values between the reference signals supplied to the adders of the neurons 4 of neuron 7.

For example, in the case where each neuron 4 of network 7 comprises a single adder 3, that is, the output signal of this neuron 4 then corresponds to the output signal of its adder 3, all the neurons 4 of layer 700 receive the same reference signal, and the neuron 4 of layer 702 receives a reference signal which is phase-shifted with respect to the reference signal of the neurons 4 of layer 700, this phase shift being determined by the sign of the sum of the increments inc_i and inc_ref of each of the adders 3 of the neurons 4 of layer 700, for example so as to compensate for the phase shift introduced by each of these adders 3.

As an alternative example, the neurons 4 of layer 700 may be of the type described in relation with FIG. 4 and each comprise two adders 3 and 3b whereas the neuron 4 of layer 702 only comprises adder 3. As another alternative example, the neurons 4 of layer 700 each only comprise adder 3, and the neuron 4 of layer 702 is of the type described in relation with FIG. 4 and comprises two adders 3 and 3b. As still another alternative example, all the neurons 4 of the neuron (or network 7) are of the type described in relation with FIG. 4 and each comprise two adders 3 and 3b. Those skilled in the art will be capable of determining the phase shifts between the reference signals supplied to the adders 3, 3b of the neurons of these alternative examples based on the present disclosure, so as to compensate for phase shifts introduced by adders 3, 3b with respect to a reference signal at frequency Fref.

Examples of neural networks organized in successive layers have been described hereabove in relation with FIGS. 5, 6, and 7, in which, in each layer, the neurons of the layer receive as inputs the output signals of neurons of the preceding layer. However, those skilled in the art will be capable of implementing other examples of neural networks organized in layers, and, in particular, examples of networks in which each neuron of a layer can receive at its input output signals from neurons of any layer(s) of the network. In other words, those skilled in the art will be capable of providing a neural network comprising a plurality of neurons, each implemented by a neuron circuit such as described in relation with FIG. 3 or with FIG. 4, and in which, in each neuron circuit, each of the K1 injection signals S_i of the adder 3 of the neuron circuit is an output signal of another neuron circuit of the network.

There has been described hereabove, in relation with FIGS. 2 to 7, embodiments of a digital injection-locked oscillator 2 and circuits and networks suitable for neural computing, in which oscillator 2 is used as a phase shifter or as a phase adder 3, 3b.

Other implementations of digital oscillators can be used as a basis for a phase adder. An example of such a digital oscillator is described hereafter in relation with FIG. 8.

FIG. 8 shows a digital ring oscillator 8 based on the oscillator 2 of FIG. 2.

More particularly, ring oscillator 8 comprises a number Q of digital oscillators 800q, with q an integer index ranging from 1 to Q, that is an integer greater than 1, preferably greater than 2. In the example of FIG. 8, Q is equal to 3, and the ring oscillator 8 thus comprises 3 digital oscillators 8001, 8002, and 8803.

One of the Q digital oscillators 800q, that is, oscillator 8001 in the example of FIG. 8, is a digital injection-locked oscillator which differs from the oscillator of FIG. 2 only by its circuit 200.

Indeed, in oscillator 8001, circuit 200 is configured, as previously described, so that value valref is selectively equal to increment inc_ref and to minus increment inc_ref according at least to the binary state of reference signal REF.

However, in FIG. 8, as compared with what has been described in relation with the previous drawings, circuit 200 is more particularly configured so that value valref is equal to increment inc_ref when the reference signal REF of oscillator 8001 is in a first binary state, and to minus increment inc_ref otherwise. In other words, as compared with the circuit 200 shown in FIG. 2, the circuit 200 of oscillator 8001 does not comprise gate 202, and selection circuit 204 is controlled directly by the signal REF of oscillator 8001.

Each of the other Q-1 digital oscillators 800q is:
either a digital injection oscillator identical to oscillator 8001, that is, which differs from the oscillator 2 of FIG. 2 in that its circuit 200 is configured so that value valref is equal to the increment inc_ref when the reference signal REF of this oscillator 800q is in a first binary state, and to minus increment inc_ref otherwise,
or a free-running digital oscillator identical to the oscillator 1 of FIG. 1, that is, a digital oscillator comprising adder 100 and register 102, and in which digital word OP2 is equal to the value of control number P.

In the example of FIG. 8, the Q-1 other oscillators 800h (8002 and 8003 in FIG. 8) are all free-running digital oscillators. In other examples not shown, the Q-1 other oscillators 800h (8002 and 8003 in FIG. 8) are all digital injection-locked oscillators identical to oscillator 8001. In still other examples not shown, the Q-1 other oscillators 800h (8002 and 8003 in FIG. 8) comprise free-running oscillators and digital injection-locked oscillators identical to oscillator 8001.

In ring oscillator 8, the Q digital oscillators 800q are connected in a ring one after the other. More particularly, the register 102 of each digital oscillator 800q is configured to be reset by a given binary state of the output bit of the digital oscillator which precedes it in the ring.

In oscillator 8, although this is not detailed in FIG. 8, the control numbers P of oscillators 800q may have different values between two oscillators 800q.

In oscillator 8, the injection locking takes place via circuits 200 of the injection-locked oscillator(s) 800q of oscillator 8. In an oscillator 8 comprising a plurality of injection-locked oscillators 800q, the reference signals REF supplied to the circuits 200 of these oscillators 800q are at the same frequency, but are phase-shifted with respect to one another. For example, these reference signals REF are phase-shifted by Π/Q with respect to one another.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. In particular, those skilled in the art will be capable of compensating for a fixed phase shift between an input signal of a digital injection-locked oscillator and a general reference signal at frequency Fref, either by a fixed phase shift between the reference signal of the oscillator and the general reference signal, or by the sign of the sum of the increments of the oscillator, or by the sign of the sum of the increments of the oscillator and by a fixed phase shift between the reference signal of the oscillator and the general reference signal.

1. Digital injection-locked oscillator comprising:
an adder configured to add a first digital word over N bits with a second digital word over N bits and to output a result of the addition in the form of a third digital word over N bits, with N an integer greater than 1;
a register configured to update the second digital word based on the third digital word at each period of a clock signal;
a first circuit configured to:
receive a reference signal at a reference frequency equal to a natural frequency of an output bit of the oscillator, and a reference increment, inc_ref,
calculate a first value selectively equal to the reference increment inc_ref and to minus the reference increment inc_ref as a function of at least one binary state of the reference signal, and
output the first digital word determined at least partly by adding the first value and a positive control number, P, of the oscillator, the output bit being a bit of the second word.

2. Oscillator according to claim 1, wherein the output bit is the most significant bit of the second digital word.

3. Oscillator according to claim 1, wherein the first circuit is configured to receive the output bit of the oscillator, and for the first value to be equal to the reference increment inc_ref if a result of an EXCLUSIVE OR between the output bit and the reference signal is in a first binary state and to minus increment inc_ref if the result of the EXCLUSIVE OR is in a second binary state.

4. Digital phase shifter comprising the oscillator according to claim 3, wherein number P belongs to a range of values centered on a number P0 and having a width equal to twice the absolute value of reference increment inc_ref, P0 being equal to 2^{L}.(Fref/Fclk), with L an index of the output bit in the second digital word, Fref the reference frequency, and Fclk the frequency of the clock signal, index L having a value in a range from 1 to N.

5. Digital phase shifter according to claim 4, wherein control number P determines a value of a phase shift of the output bit with respect to the reference signal.

6. Digital phase shifter according to claim 4, wherein the first digital word is equal to the sum of the first value and of the control number P of the oscillator.

7. Digital phase shifter according to claim 4, wherein the output bit is phase-shifted by φ with respect to the reference signal, with:
$$φ = \frac{π}{2} + π \frac{P - {P}_{0}}{2 * inc\_ref} if inc\_ref has a first polarity , and$$
$$φ = - \frac{π}{2} + π \frac{P - {P}_{0}}{2 * {inc}_{ref}} if {inc}_{ref} has a second polarity opposite to the first polarity .$$

8. Digital phase adder comprising:
the oscillator according to claim 3, wherein:
the first circuit comprises K second circuits Lock_i, with i an integer index ranging from 1 to K and K an integer greater than or equal to 1, each second circuit Lock_i being configured to:
receive the output bit, an increment inc_i, and an injection signal S_i at a frequency equal to the reference frequency with a phase shift φ_i with respect to the reference signal, and
output a second value out_i equal to increment inc_i if a result of an EXCLUSIVE OR result between the output bit and injection signal S_i is in a first binary state, and minus increment inc_i otherwise; and
the first circuit is configured to deliver the first digital word equal to the sum of control number P, of the first value, and of the K second values val_i.

9. Digital phase adder according to claim 8, wherein control number P is equal to 2^{L}.(Fref/Fclk), with L an index of the output bit in the second digital word, Fref the reference frequency, and Fclk the frequency of the clock signal, index L having a value in a range from 1 to N.

10. Digital phase adder according to claim 8, wherein the output bit is phase-shifted by φ with respect to the reference signal, with:
$$A = inc\_ref + {\sum }_{i = 1}^{i = K} inc\_i$$
$$φ = \frac{π}{2} + {\sum }_{i = 1}^{K} \frac{inc\_i \cdot D\_i}{A} if A has a first polarity ,$$
$$φ = - \frac{π}{2} + {\sum }_{i = 1}^{K} \frac{inc\_i \cdot D\_i}{A}$$
if A has second polarity opposite to the first polarity.

11. Neuron circuit comprising a first digital phase adder according to claim 8, wherein K is equal to K1 in the first adder, the K1 phase shifts φ_i of the first adder correspond to K1 input values of the neuron circuit, K1 weights w_i of the neuron circuit determine the K1 increments inc_i of the first adder and of the reference increment inc_ref of the first adder, and K1 is greater than or equal to 2.

12. Neuron circuit according to claim 11, wherein the K1 increments inc_i of the first adder and the reference increment inc_ref of the first adder satisfy:
$$- inc\_i + {\sum }_{i = 1}^{i = K 1} w\_j \cdot inc\_i = - w\_j \cdot inc\_ref ,$$
with j an integer index ranging from 1 to K1, and
$$\vert inc\_ref \vert + {\sum }_{i = 1}^{i = K 1} \vert inc\_i \vert < P 1 ,$$
with ∥ the absolute value operator, and P1 the value of the number P of the first adder.

13. Neuron circuit comprising a first digital phase adder and a second digital phase adder according to claim 8,
wherein, for the first digital phase adder, K is equal to K1 in the first adder, the K1 phase shifts φ_i of the first adder correspond to K1 input values of the neuron circuit, K1 weights w_i of the neuron circuit determine the K1 increments inc_i of the first adder and of the reference increment inc_ref of the first adder, and K1 is greater than or equal to 2,
and wherein, for the second digital phase adder, K is equal to K2 in the second adder and the output bit of the first adder corresponds to one of the K2 injection signals of the second adder.

14. Neuron circuit according to claim 13, wherein the reference signal of the second adder has a same frequency as the reference signal of the first adder, and a phase shift between the reference signal of the first adder and the reference signal of the second adder is determined by a sign of the sum of the increments inc_i and inc_ref of the first adder, preferably so as to compensate for a phase shift introduced by the first adder.

15. Neural network comprising M successive layers of neurons, with M an integer greater than 1, and h an integer index ranging from 1 to M and increasing from inputs to outputs of the network, wherein:
each neuron is implemented by a neuron circuit according to claim 11 in which the output bit of the first adder of the neuron circuit is the output bit of the neuron;
the neurons of the layers of odd indices h all receive a same reference signal; and
each of the neurons of the layers of even indices h receives a reference signal at a same frequency as the reference signal of the neurons of the layers of odd indices h, but with a phase shift between these two reference signals determined by a sign of the sum of the increments inc_i and inc_ref of each of the first adders of the neurons of the layers of odd indices h.

16. Neural network comprising a plurality of layers of neurons, wherein:
each neuron is implemented by a neuron circuit according to claim 13,
the first adders of the neurons of the network all receive a same reference signal.

17. Neural network comprising a plurality of neurons, each implemented by a neuron circuit according to claim 11, wherein, in each neuron circuit, each of the K1 injection signals of the first adder is an output bit of another neuron circuit of the network.

18. Ring oscillator comprising Q digital oscillators, with Q an integer greater than 1, preferably then 2, wherein:
one of the Q digital oscillators is a digital injection-locked oscillator according to claim 1 in which the first value is equal to the reference increment inc_ref of this digital injection-locked oscillator when the reference signal of this digital injection-locked oscillator is in a first binary state, and to minus reference increment inc_ref otherwise;
each of the Q-1 other digital oscillators is:
either a digital injection-locked oscillator according to claim 1 in which the first value is equal to the reference increment inc_ref of this digital injection-locked oscillator when the reference signal of this digital injection-locked oscillator is in a first binary state, and to minus reference increment inc_ref otherwise,
or a free-running digital oscillator comprising:
an adder configured to add a first digital word over N bits with a second digital word over N bits and to deliver a result of the addition in the form of a third digital word over N bits; and
a register configured to update the second digital word based on the third digital word at each period of the clock signal, an output bit of said free-running oscillator being a bit of the third word and the first digital word being a word for controlling said free-running oscillator,
wherein the Q digital oscillators are connected in a ring one after the other, the register of each digital oscillator being configured to be reset by a state of the output bit of the preceding digital oscillator (8003, 8001, 8002) in the ring.
